(19) United States
(12) Patent Application Publication
(10) Pub. No.: US 2020/0028349 A1
(43) Pub. Date: Jan. 23, 2020

(54) SYSTEM AND METHOD FOR DETECTING ARC FAULTS

(71) Applicant: GE Aviation Systems Limited, Cheltenham (GB)

(72) Inventor: David Alan Elliott, Gloucestershire (GB)

(21) Appl. No.: 16/275,357

(22) Filed: Feb. 14, 2019

(30) Foreign Application Priority Data
Mar. 1, 2018 (GB) 1803341.5

(51) Int. Cl. H02H 3/28; G01R 31/08; G01R 15/16; H02H 1/00; H02H 3/44; H02H 7/26

(52) U.S. Cl. CPC H02H 3/28; G01R 31/086; H02H 7/263; H02H 1/0015; H02H 3/44; G01R 15/16

(57) ABSTRACT

A system and method for detecting arc faults includes receiving, by a controller module, a first sensed power characteristic from a first power characteristic sensor at an output of an upstream electrical component, receiving, by the controller module, a second sensed power characteristic from the second power characteristic sensor at an input of a downstream electrical component, the input and output connected by a conductor, determining, by the controller module, a difference between the first and second sensed power characteristics, and providing indication of an arc fault at the conductor.

### BACKGROUND

Electrical systems, such as those found in an aircraft power distribution system, employ electrical bus bars and miles of wiring for delivering power from electrical power sources to electrical loads. In the event of an electrical arc fault or other failure condition, high currents might be transmitted through a normally nonconductive medium, such as air, with unexpected consequences for the power distribution system at or about the arcing failure point.

### BRIEF DESCRIPTION

In one aspect, the present disclosure relates to a power distribution system including an upstream electrical component having an output and a first power characteristic sensor configured to sense a power characteristic at the output, a downstream electrical component having an input and a second power characteristic sensor configured to sense a power characteristic at the input, a conductor conductively connecting the output with the input, and a controller module having an arc fault threshold stored in memory and communicatively connected with the first and second power characteristic sensors and configured to determine if an arc fault is present by receiving a first sensed power characteristic from the first power characteristic sensor and a second sensed power characteristic from the second power characteristic sensor, determining a difference between the first and second sensed power characteristics, determining a calibration factor and modifying the arc fault threshold based on the calibration factor, comparing the difference with the modified arc fault threshold, and upon satisfaction of the comparison, providing indication of an arc fault at the conductor. The calibration factor includes at least one of a temperature factor, a current factor, or a timing factor.

In another aspect, the present disclosure relates to a method for detecting arc faults in a power distribution system, the method including receiving, in a controller module, a first sensed power characteristic from a first power characteristic sensor at an output of an upstream electrical component, receiving, in the controller module, a second sensed power characteristic from a second power characteristic sensor at an input of a downstream electrical component, the input and output connected by a conductor, determining, by the controller module, a difference between the first and second sensed power characteristics, determining, by the controller module, a fault threshold calibration factor, modifying an arc fault threshold stored in memory of the controller module based on the fault threshold calibration factor, comparing the determined difference with the modified arc fault threshold, and upon satisfaction of the comparison, providing indication of an arc fault at the conductor. The fault threshold calibration factor includes at least one of a temperature factor, a current factor, or a timing factor.

### BRIEF DESCRIPTION OF THE DRAWINGS

In the drawings:

FIG. 1 is a top down schematic view of the aircraft and power distribution system of an aircraft in accordance with various aspects described herein.

FIG. 2 is a schematic view of a power distribution system and the occurrence of a series arc fault, in accordance with various aspects described herein.

FIG. 3 is a schematic view of another power distribution system and the occurrence of a series arc fault, in accordance with various aspects described herein.

FIG. 4 is a schematic view of a power distribution system and the occurrence of a parallel arc fault, in accordance with various aspects described herein.

FIG. 5 is a schematic view of another power distribution system and the occurrence of a parallel arc fault, in accordance with various aspects described herein.

### DESCRIPTION OF THE DISCLOSURE

The described aspects of the present disclosure are directed to an electrical power distribution system, which can be used, for example, in an aircraft. While this description is primarily directed toward a power distribution system for an aircraft, it is also applicable to any environment using an electrical system for transmitting power from a power source to an electrical load.

While “a set of” various elements will be described, it will be understood that “a set” can include any number of the respective elements, including only one element. Also as used herein, while sensors can be described as “sensing” or “measuring” a respective value, sensing or measuring can include determining a value indicative of or related to the respective value, rather than directly sensing or measuring the value itself. The sensed or measured values can further be provided to additional components. For instance, the value can be provided to a controller module or processor, and the controller module or processor can perform processing on the value to determine a representative value or an electrical characteristic representative of said value.

Connection references (e.g., attached, coupled, connected, and joined) are to be construed broadly and can include intermediate members between a collection of elements and relative movement between elements unless otherwise indicated. As such, connection references do not necessarily infer that two elements are directly connected and in fixed relation to each other. In non-limiting examples, connections or disconnections can be selectively configured, connected, or connectable to provide, enable, disable, or the like, an electrical connection between respective elements. Non-limiting example power distribution bus connections or disconnections can be enabled or operated by way of switching, bus tie logic, or any other connectors configured to enable or disable the energizing of electrical loads downstream of the bus.

As used herein, a “system” or a “controller module” can include at least one processor and memory. Non-limiting examples of the memory can include Random Access Memory (RAM), Read-Only Memory (ROM), flash memory, or one or more different types of portable electronic memory, such as discs, DVDs, CD-ROMs, etc., or any suitable combination of these types of memory. The processor can be configured to run any suitable programs or executable instructions designed to carry out various methods, functionality, processing tasks, calculations, or the like, to enable or achieve the technical operations or operations described herein. The program can include a computer program product that can include machine-readable media for carrying or having machine-executable instructions or data structures stored thereon. Such machine-readable media can be any available media, which can be accessed by a general purpose or special purpose computer or other machine with a processor. Generally, such a computer program can include routines, programs, objects, components, data structures, algorithms, etc., that have the technical effect of performing particular tasks or implement particular abstract data types.

As used herein, a controllable switching element, or a “switch” is an electrical device that can be controllable to toggle between a first mode of operation, wherein the switch is “closed” intending to transmit current from a switch input to a switch output, and a second mode of operation, wherein the switch is “open” intending to prevent current from transmitting between the switch input and switch output. In non-limiting examples, connections or disconnections, such as connections enabled or disabled by the controllable switching element, can be selectively configured to provide, enable, disable, or the like, an electrical connection between respective elements.

Non-limiting aspects of the disclosure can be implemented in any electrical circuit environment having a switch. A non-limiting example of an electrical circuit environment that can include aspects of the disclosure can include an aircraft power system architecture, which enables production of electrical power from at least one spool of a turbine engine, preferably a gas turbine engine, and delivers the electrical power to a set of electrical loads via at least one solid state switch, such as a solid state power controller (SSPC) switching device. One non-limiting example of the SSPC can include a silicon carbide (SiC) or Gallium Nitride (GaN) based, high power switch. SiC or GaN can be selected based on their solid state material construction, their ability to handle high voltages and large power levels in smaller and lighter form factors, and their high speed switching ability to perform electrical operations very quickly. Additional switching devices or additional silicon-based power switches can be included.

The aspects of the disclosure can be implemented in any electrical circuit environment having a switch. A non-limiting example of an electrical circuit environment that can include aspects of the disclosure is an aircraft power system architecture, which enables production of electrical power from at least one spool of a turbine engine, preferably a gas turbine engine, and delivers the electrical power to a set of electrical loads via at least one solid state switch, such as a solid state power controller (SSPC) switching device. One non-limiting example of the SSPC can include a silicon carbide (SiC) or Gallium Nitride (GaN) based, high power switch. SiC or GaN can be selected based on their solid state material construction, their ability to handle high voltages and large power levels in smaller and lighter form factors, and their high speed switching ability to perform electrical operations very quickly. Additional switching devices or additional silicon-based power switches can be included.

Additionally, as used herein, an electrical arc or arcing event is an untended or undesired conduction of current across a traditionally non-conductive medium, such as air. For example, in non-limiting instances, a parallel arc can include an arcing event at least partially connecting two points which are intended to be insulated from each other. In another non-limiting instance, a series arc can include an arcing event in which a conductive medium becomes non-conductive or poorly conductive between two parts of an intended conductive path. Furthermore, in non-limiting instances, an arcing event or an “arc fault” can include the unexpected power loss situation, regardless of whether there is an obvious arc manifestation (e.g. a visible or visually identifiable occurrence). In another non-limiting instance, a series arc can include an unexpected impedance.

Electrical arcs might occur in an environment where, for example, physical defects in an electrical connection cause a permanent or temporary loss in transmission capabilities. Where a physical separation occurs, the voltage difference between each of the separated terminals in addition to a short distance of separation, can allow for an electrical arc to strike between the terminals. In an environment with vibrations, for instance, as in a moving aircraft, a physical defect in an electrical connection might result in intermittent arcing events as the vibrations disconnect and reconnect the electrical connection at the point of the physical defect. In another example aspect, an electrical arc might be caused by, or relate to a loose terminal connection, or a drawn series fault.

The exemplary drawings are for purposes of illustration only and the dimensions, positions, order and relative sizes reflected in the drawings attached hereto can vary.

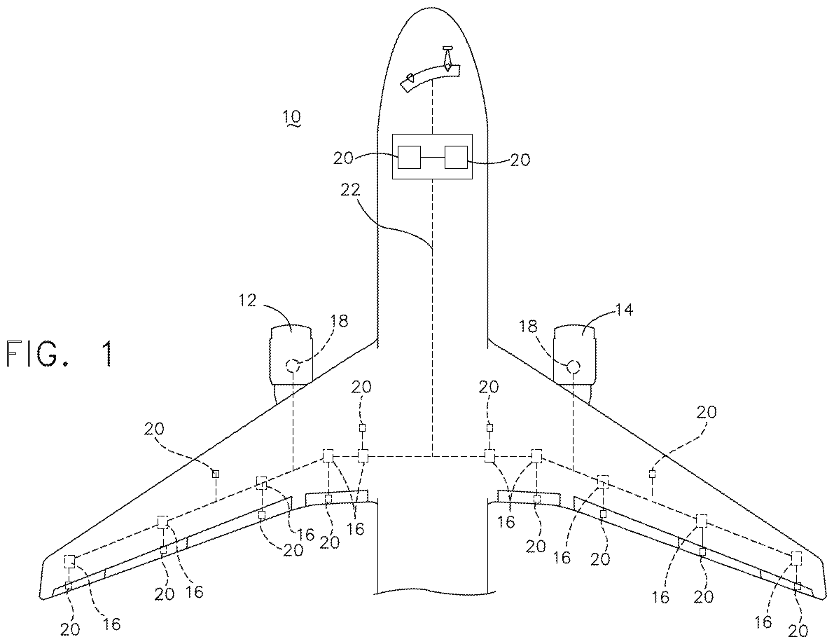

As illustrated in FIG. 1, an aircraft 10 is shown having at least one gas turbine engine, shown as a left engine system 12 and a right engine system 14. Alternatively, the power system can have fewer or additional engine systems. The left and right engine systems 12, 14 can be substantially identical, and can further include at least one power source, such as an electric machine or a generator 18. The aircraft is shown further having a set of power-consuming components, or electrical loads 20, such as for instance, an actuator load, flight critical loads, and non-flight critical loads. The electrical loads 20 are electrically coupled with at least one of the generators 18 via a power distribution system including, for instance, power transmission lines 22 or bus bars, and power distribution nodes 16. It will be understood that the illustrated aspect of FIG. 1 is only one non-limiting example of a power distribution system, and many other possible aspects and configurations in addition to that shown are contemplated by the present disclosure. Furthermore, the number of, and placement of, the various components depicted in FIG. 1 are also non-limiting examples of aspects associated with the disclosure.

In the aircraft 10, the operating left and right engine systems 12, 14 provide mechanical energy which can be extracted, typically via a spool, to provide a driving force for the generator 18. The generator 18, in turn, generates power, such as alternating current (AC) or direct current (DC) power, and provides the generated power to the transmission lines 22, which deliver the power to the power distribution nodes 16, positioned throughout the aircraft 10. The power distribution nodes 16 receive the AC or DC power via the transmission lines 22, and can provide switching, power conversion, or distribution management functions, as needed, in order to provide the desired electrical power to the electrical loads 20 for load operations.

Example power distribution management functions can include, but are not limited to, selectively enabling or disabling the delivery of power to particular electrical loads 20, depending on, for example, available power distribution supply, criticality of electrical load 20 functionality, or aircraft mode of operation, such as take-off, cruise, or ground operations. Additional management functions can be included. Furthermore, additional power sources for providing power to the electrical loads 20, such as emergency power sources, ram air turbine systems, starter/generators, batteries, or the like can be included, and substitute for or supplement the power source. It will be understood that while one aspect is shown in an aircraft environment, the disclosure is not so limited and has general application to electrical power systems in non-aircraft applications, such as other mobile applications and non-mobile industrial, commercial, and residential applications.

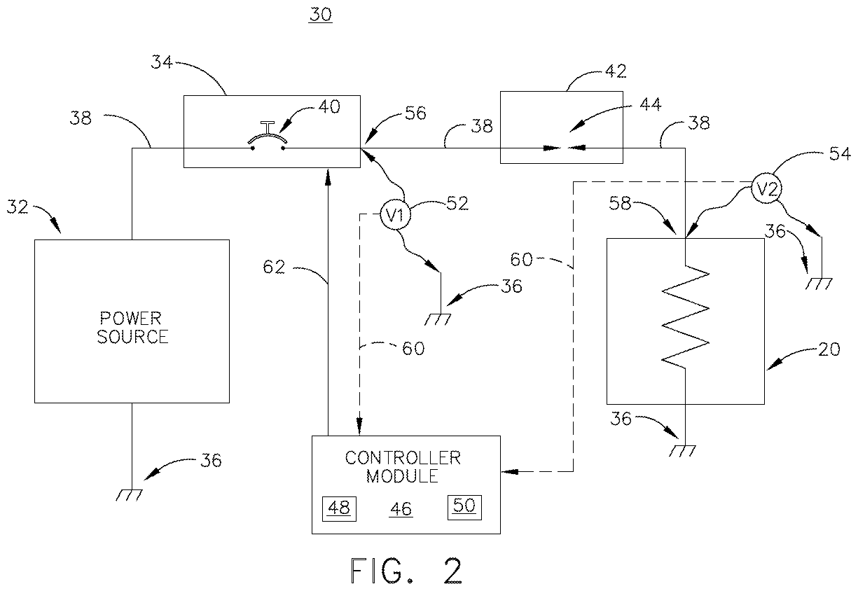

FIG. 2 illustrates a non-limiting schematic example of a power distribution system 30 of the aircraft 10. As shown, the power distribution system 30 can include at least one power source 32, a switchable components, such as a SSPC 34 including a representative switching element 40, the electrical load 20 (shown schematically as a resistor), and a conductor 38 electrically connecting the power source 32, SSPC 34, and the electrical load 20. Each of the power source 32 and electrical load 20 can further be electrically connected to an electrical ground 36. Non-limiting aspects of the electrical ground 36 can include a common electrical grounding, an earth ground, a common frame, such as the aircraft frame, or the like.

The power distribution system 30 can further include a controller module 46 having a processor 48 and memory 50. The controller module 46 can be configured or adapted to execute controllable operations, for instance, in response to received signals, data, or the like, and generate control commands, signals, or another enabling or operative functional output. For instance, as shown, the controller module 46 can be communicatively connected with the SSPC 34 by way of a signal output pathway 62, and be configured or adapted to operably control the switching functionality of the switching element 40. In one non-limiting aspect, the controller module 46 can include, or form a portion of, a power management monitoring and control (PMMC) unit.

FIG. 2 further illustrates a representative arc fault 42 occurring in a segment of the conductor 38. The specific position of the arc fault 42 illustrated is merely one non-limiting example of a schematic arcing event. Aspects of the disclosure can be included wherein arc faults 42 anywhere on a conductive connection can be detected, identified, and the like, in accordance herein, and the actual position of the arc fault 42. In this example, the arc fault 42 can include a series arc fault 44 occurring downstream of an output 56 of the SSPC 34 and upstream of an input 58 of the electrical load 20. While the schematic view of FIG. 2 does not show a large conductor 38 length or span between the power source 32 or the SSPC 34 and the electrical load 20, in a non-limiting aspect of an actual aircraft 10 environment, the conductor 38 length or span between the power source 32 or the SSPC 34 and the electrical load 20 can be a long distance, on the order of meters.

Non-limiting aspects of the disclosure can be included wherein a set of power characteristic sensors can be positioned, disposed, placed, or the like, relative to components of the power distribution system 30. For example, as shown, a power characteristic sensor, such as a first voltage sensor 52, can be positioned between the output 56 of the SSPC 34 and an electrical ground 36, and another power characteristic sensor, such as a second voltage sensor 54 can be positioned between the input 58 of the electrical load 20 and an electrical ground 36. In each instance, the respective voltage sensors 52, 54 can be configured, adapted, enabled, or the like to sense or measure a voltage at the respective locations. The set of voltage sensors 52, 54 can further be communicatively connected with the controller module 46, for instance, by way of communication lines 60, and can provide the sensed voltage, or a communication representative thereof, to the controller module 46.

The initial manifestation of a series arc fault 44, such as increased voltage drop across a pair of terminals, can be relatively minor and the electrical load 20 may continue to perform its normal function. However, the arc fault 44 or arcing event can progressively increase damage to the contact surfaces and hence increase heat production. This may result in a thermal run-away situation with much more serious damage including failure of surrounding insulation and damage to adjacent circuits. Timely detection and appropriate action during the early phase of a series arc fault 44 can greatly improve the expected operations of the power distribution system 30 as well as minimizing the loss of electrical load 20 functionality.

Some non-limiting aspects of arc protection systems are based on performing a pattern recognition task to search for an arc ‘signature’ in the waveform obtained from a series of current or voltage measurements as a function of time. This signature recognition or detection of the arc current or voltage waveforms can be affected by environmental characteristics, which in the environment of an aircraft 10 can include vibration, presence of transmission characteristics of connecting wires or conductors 38, insulating materials, presence of liquids and vapors including water, material, shape and size of the conductors, or the like. Furthermore, non-limiting aspects of electrical loads 20, such as brushed motors, can produce, result in, or detect waveforms which will vary with usage as the brushes wear. In addition, voltage drops causing power loss and heating can occur by additional or alternative mechanisms, including but not limited to worn contact surfaces at connectors, relays, switches, or the like. Such voltage drops can give rise to direct problems including excess heat production, as well as being a precursor stage to full-scale arcing event. However, such leakage may involve little or no arcing and is unlikely to trigger an arcing signature recognition, and thus can be ‘undetectable’ by such arc protection systems.

Furthermore, the improper detection of an arc fault (where there is, in fact, no arc fault or arcing event occurrence), in turn, affects or interrupts operation of at least a portion of the power distribution system, resulting in a “nuisance trip.” Alternatively, variance in detected waveforms can also be undetected by detection systems, even when they may indicate arc-possible instances.

Aspects of the disclosure enable, or otherwise are adapted or configured to the improve detection sensitivity by applying knowledge of the different manners in which the observed voltages will be affected by an arc fault 42 and by measurement errors, thereby minimizing the allowance that must be made for the measurement errors and consequently improving the arc fault 42 detection sensitivity. Reducing the measurement errors also reduces the probability of sensor, data, or detection discrepancies being sufficiently large to trigger a false detection. Non-limiting aspects of the disclosure can be included wherein the SSPC 34 or electrical loads 20 includes or incorporates integrated voltage sensors 52, 54.

Non-limiting aspects of the disclosure can be configured or adapted to sense or measure the voltage at at least two locations in each power distribution system 30 to determine the voltage drop between the at least two locations. For example, as shown in FIG. 2, the first and second voltage sensors 52, 54 can sense or measure the respective voltages at the output 56 of the SSPC 34 and the input 58 of the electrical load 20. In another non-limiting example, the sensed or measured voltages from the first and second voltage sensors 52, 54 can be supplied, provided, delivered, or communicated to the controller module 46, which can be adapted or configured to determine the voltage drop between the respective locations. Detection of a voltage drop exceeding a value, threshold, range, or the like can imply an arc fault 42 condition, such as the series arc fault 44. In one non-limiting example, the value, threshold, range, or the like can by predetermined or dynamic, and can be stored in memory 50 of the controller module 46. The controller module 46 can be adapted to compare the determined voltage drop with the value, threshold, range, or the like. Upon satisfaction of the comparison, the controller module 46 can determined whether an arc fault 42 is or has occurred.

Non-limiting aspects of the disclosure can be included wherein the sensitivity of detecting arc faults 42 in the power distribution system 30 based on comparison of sensed voltages can be limited by the accuracy of the respective voltage sensor 52, 54 of power distribution system 30. For example, the error margins of each sensed or measured voltage may exceed plus or minus 5%, and hence a series arc fault 44 that progressively increases in intensity may not be detected in the earlier stages that are more benign from a safety viewpoint due to comparatively small voltage drop determined by the controller module, especially when adapted or configured to avoid nuisance trips.

Thus non-limiting aspects of the disclosure can incorporate a non-limiting set of considerations adapted or configured to minimize the effect of the errors in each voltage difference determination by the controller module 46. In another non-limiting aspect, the disclosure described herein can allow for accurate detection of arc faults 42 without the expense and complexity of implementing high accuracy voltage measurements throughout the power distribution system 30.

In one non-limiting example of FIG. 2, the power distribution system 30 can include a 28 Volt DC aircraft application, wherein the conductor 38 is designed to meet the requirement that the conductor 38 voltage drop from the output of the SSPC 34 to the load is less than 1 Volt. In the above-mentioned examples, a maximum threshold value or range can be determined. For instance, if each voltage sensor 52, 54 includes a maximum of 5% error, and the power source is 28 Volts, the largest voltage difference between the first and second voltage sensors 52, 54 can be 5 Volts for a non-fault determination. This includes reading the maximum sensed voltage by the first voltage sensor 52 (28 Volts plus 2 Volts, approximately a 5% error, equals 30 Volts sensed), the expected 1 Volt drop across the conductor 38, and the minimum sensed voltage by the second voltage sensor 54 (27 Volts, after the 1 volt conductor 38 drop, minus 2 Volts, approximately a 5% error, equals 25 Volts sensed; 30 volts minus 25 volts equals a 5 Volt threshold for a non-fault determination).

Furthermore, aspects of the disclosure can be included wherein each voltage measurement point is always measured by the same power characteristic sensor, voltage sensor 52, 54, or the like, and similarly, the circuit and interconnecting conductor 38 remains the same (e.g. unless replaced during maintenance, etc.). Thus, the error discrepancies should also remain unchanged providing the sensed or measured power characteristic conditions, such as temperature and current flow, are appropriately considered. Thus, in non-limiting aspects of the disclosure, the detection of an arc fault 42 can be achieved by discovering an unexpected change of observed voltage measurements even though it is smaller than the absolute error margins. However, the observed voltage difference can be affected by a number of factors including the current flow at that moment in time. A non-limiting set of factors and approaches to minimize their influence on the sensitivity of the fault detection capability, are included below. While aspects of the disclosure can include all of factors described herein, it is appreciated that an implementation using a subset of the factors can provide a sufficient sensitivity improvement.

In one non-limiting example, a first factor can include environmental conditions of the power distribution system 30. For example, a copper wire conductor 38 for a 28 V DC aircraft load may be specified to have a maximum voltage drop between an upstream terminal or connection point to a downstream terminal or connection point to be less a than 1.0 V under all environmental conditions. Thus, if it is 1.0 V at 150 degree Celsius and maximum current, it could be 0.6 V at −50 degrees Celsius, when all other conditions including current is unchanged. As used herein, temperature of disclosure aspects, including the conductor 38, can be directly affected by an amount of current traversing the component. Non-limiting aspects of the disclosure can be included wherein the power distribution system 30, the controller module 46, or the like include a temperature sensor, a temperature reading, or a temperature measurement, as needed, for providing temperature-based computations, measurements, considerations, or the like.

If the temperature of the conductor 38 can be assessed, then appropriate compensation can be applied using standard engineering calculations or known values. Similarly, the voltage drop can decrease in proportion to reduction in current, so that if the current is measured, the total voltage drop allowance can be reduced using standard engineering calculations or known values. However, it may be noted that the maximum change in this example for both factors is included in the actual or determined values (e.g. the maximum change in the conductor 38 is 1.0 V, when combining the expected, desired, or known current and temperature values or considerations. Thus, non-limiting aspects of the disclosure can be included wherein the voltage drops across the conductor 38 less than 1.0 V could be ignored, when a detected arc fault 42 will exceed this value.

In another non-limiting example consideration or factor of the power distribution system 30, can include a timing factor. For example, environmental changes as described above are likely going to be sensed, measured, determined, or the like over a period of time in the range of 1 millisecond to a few hours. In contrast, a voltage difference due to an arc event 42 is expected to change rapidly. For example, a change in temperature over time would “appear” smooth over time, as sensed by the voltage sensors 52, 54. In contrast, an arc fault 42 would likely include abrupt or sudden voltage changes, for example due to vibrational contacting of the arcing terminals of the conductor 38.

By incorporating at least a subset of environmental considerations or factors such as temperature, current, calibrations, and the like, or timing considerations or factors, in the determination of an arc fault 42 occurrence, the power distribution system 30 can more accurately determined the occurrence of a “true” arc fault 42, as opposed to false or nuisance arc fault occurrence. Non-limiting aspects of the disclosure can be included wherein the temperature, current, calibrations, and the like, can be factored into the determination whether an arc fault 42 is or has occurred during start up, repeatedly over a period of time (e.g. if the temperature rises over time, a new calibration can occur), during interval time periods, or on-demand, for example, to validate or verify a suspected arc fault 42 detection or determination. The aforementioned considerations, factors, or the like, can be included in the value, threshold, range, or the like. For example, in one non-limiting aspect of the disclosure, the value, threshold, range, or the like can include a timing component or factor, which needs to be satisfied for determining an arc fault 42 has or is occurring (e.g. exceeding a 5 V difference for longer than 1 millisecond, or exceeding a 1.5 V difference for longer than 1 second can result in a determination of an arc fault).

Furthermore, non-limiting aspects of the disclosure can be included wherein the aforementioned considerations, factors, or the like, or the value, threshold, or range can be tailored or selected when determining a fault is, has, or is likely to occur. For example, old, aged, or contaminated components, such as with a switch or contactor, can at least partially prevent electrically conductive components from achieving a close electrical contact. In some instances, such aged or contaminated components can develop into a series fault or series arc fault, but can still be sensed and measured in the current disclosure as a voltage difference. In one non-limiting aspect, the disclosure can be tailored to sense and compare the voltage difference, as described herein, to identify aged or contaminated components, and identify, for example, by way of comparison, considerations, factors, or the like, that a fault is likely to occur, even in the absence of an actual or physical arcing event. Similarly, contamination or the like between adjacent parallel conductors can likewise introduce an unexpected current flow, which aspects of the disclosure can be tailored or selected to identify a parallel fault, or that a fault is likely to occur, even in the absence of an actual or physical arcing event. In these non-limiting instances, the pre-arcing faults can be considered “arcing events” or “arc faults” for the purposes of aspects of the disclosure, and can be detected by way of the aforementioned factors, considerations, comparisons, and the like.

Employing separate voltage sensors 52, 54, such that the controller module 46 can determine the voltage difference, removes the need for a separate, specialized, or additional voltmeter probe to span the distance from the terminal ends at which the voltage is being sensed or measured (e.g. a probe spanning the output 56 of the SSPC 34 to the input 58 of the electrical load 20). Upon determining an arc fault 42, such as a series arc fault 44 is or has occurred, non-limiting aspects of the disclosure can be included wherein the power distribution system 30, the controller module 46, or a combination thereof, can employ remedial measures, actions, alerts or notifications, or the like to stop, reduce, identify, call attention to, or extinguish the arc fault 42. In one non-limiting aspect of the disclosure, the remedial measures can include generating a control signal or controllably operating the power source 32, the SSPC 34, or a combination thereof, for example, by way of the signal output pathway 62. In such an example, disconnecting the switchable element 40 or SSPC 34 can operate as a circuit breaker to extinguish he arc fault 42.

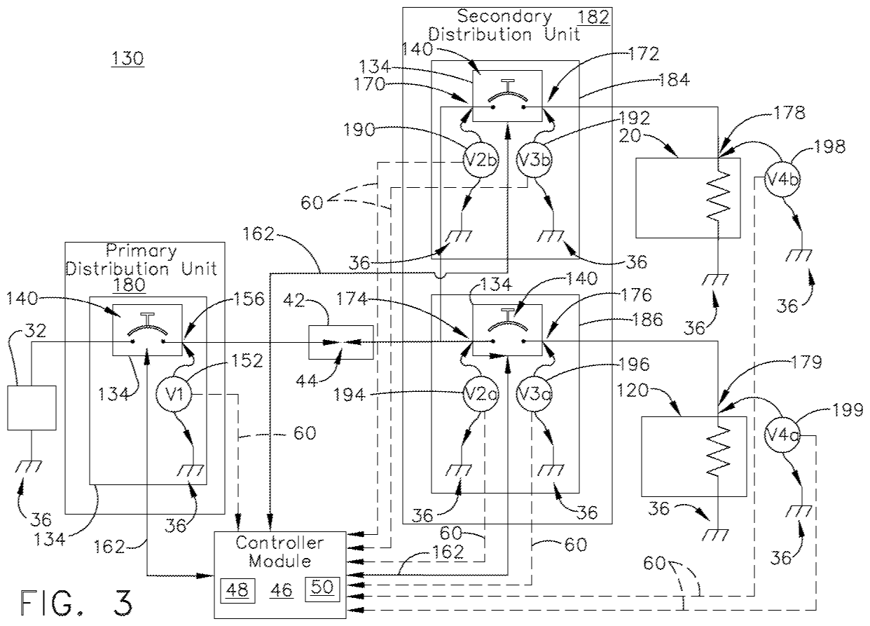

FIG. 3 illustrates another power distribution system 130 according to another aspect of the present disclosure. The power distribution system 130 is similar to the power distribution system 30; therefore, like parts will be identified with like numerals increased by 100, with it being understood that the description of the like parts of the power distribution system 30 applies to the power distribution system 130, unless otherwise noted. One difference is that the power distribution system 130 includes multi-tiered power distribution network, described below.

As shown, the power distribution system 30 can include the power source 32 connected upstream of a primary power distribution unit 180, which is further connected upstream in parallel with a set of secondary power distribution units 182, shown as a first secondary power distribution unit 184 and a second secondary power distribution unit 186. The primary distribution unit 180 can include an SSPC 134 having a switching element 140, and a power characteristic sensor, such as a first voltage sensor 152, positioned at an output 156 of the SSPC 134 or the primary distribution unit 180. The SSPC 134 or the switchable element 140 can be controllably or communicatively connected with the controller module 46 by way of a signal output pathway 162.

The first secondary distribution unit 184 can include an SSPC 134 having a switching element 140, and at least one a power characteristic sensor, such as a second voltage sensor 190 positioned at an input 170 of the SSPC 134 or the first secondary distribution unit 184 and a third voltage sensor 192 positioned at an output 172 of the SSPC 134 or the first secondary distribution unit 184. Similarly, the second secondary distribution unit 186 can include an SSPC 134 having a switching element 140, and at least one a power characteristic sensor, such as a fourth voltage sensor 194 positioned at an input 174 of the SSPC 134 or the second secondary distribution unit 186 and a fifth voltage sensor 196 positioned at an output 176 of the SSPC 134 or the second secondary distribution unit 186. In non-limiting examples, each of the SSPCs 134 or switching elements 140 can be controllably or communicatively connected with the controller module 46 by way of a respective signal output pathway 162.

As shown, the output 172 of the first secondary distribution unit 184 can be connected upstream of a first electrical load 20 at an input 178. A power characteristic sensor, such as a sixth voltage sensor 198 can be positioned at the input 178 of the first electrical load 20. Also as shown, the output 176 of the second secondary distribution unit 186 can be connected upstream of a second electrical load 120 at an input 179. A power characteristic sensor, such as a seventh voltage sensor 199 can be positioned at the input 179 of the second electrical load 120. Each respective voltage sensor 152, 190, 192, 194, 196, 198, 199 can further be communicatively connected with the controller module 46, for instance, by way of communication lines 60, and can provide the sensed voltage, or a communication representative thereof, to the controller module 46.

As described herein, aspects of the disclosure enable, or otherwise are adapted or configured to the improve detection sensitivity by applying knowledge of the different manners in which the observed voltages will be affected by an arc fault 42 and by measurement errors, thereby minimizing the allowance that must be made for the measurement errors and consequently improving the arc fault 42 detection sensitivity.

Non-limiting aspects of the disclosure can be configured or adapted to sense or measure the voltage at at least two locations in each power distribution system 130 to determine the voltage drop between the at least two locations. For instance, non-limiting aspects of the disclosure can detect, calculate, or otherwise determine a voltage drop between at least two locations of the power distribution system 130, such as between the output 156 of the primary power distribution unit 180 and the input of the 170 of the first secondary distribution unit 184, between the output 156 of the primary power distribution unit 180 and the input of the 174 of the second secondary distribution unit 186, between the output 172 of the first secondary distribution unit 184 and the input 178 of the first electrical load 20, between the output 176 of the second secondary distribution unit 186 and the input 179 of the second electrical load 120, or a combination thereof.

As described herein, the respective voltage sensors 152, 190, 192, 194, 196, 198, 199 can sense or measure the respective voltages at the respective inputs or outputs 156, 170, 172, 174, 176, 178, 179. In another non-limiting example, the sensed or measured voltages from the respective voltage sensors 152, 190, 192, 194, 196, 198, 199 can be supplied, provided, delivered, or communicated to the controller module 46, which can be adapted or configured to determine the voltage drop between respective locations 156, 170, 172, 174, 176, 178, 179. Non-limiting aspects of the disclosure can include sequentially respective locations (e.g. between the output 172 of the first secondary distribution unit 184 and the input 178 of the first electrical load 20) or respective locations with intervening components (e.g. between the output 156 of the primary distribution unit 180 and the input 178 of the first electrical load 20). Detection of a voltage drop exceeding a value, threshold, range, or the like can imply an arc fault 42 condition, such as the series arc fault 44. The specific position of the arc fault 42 illustrated is merely one non-limiting example of a schematic arcing event. Non-limiting aspects of the disclosure can be included wherein the power distribution system 130, the controller module 46, or the like, can define a set of values, thresholds, ranges, or the like, such that each electrical span between respective voltage sensors 152, 190, 192, 194, 196, 198, 199 can define an individual threshold. In yet another non-limiting instance, additional or fewer voltage sensors 152, 190, 192, 194, 196, 198, 199 can be included or positioned as desired for reducing component counts, increasing reliability, or the like. For example, second voltage sensor 190 and fourth voltage sensor 194 can effectively have the same voltage measurement, so one could be eliminated. Alternatively, both the second and fourth voltage sensors 190, 194 can be included to determine if a-fault occurs between the sensors 190, 194.

Furthermore, non-limiting aspects of the disclosure can be included wherein the controller module 46 can be configured or adapted to determined where the arc fault 42 is or has occurred, based on the respective sensed voltages received from the set of voltage sensors 152, 190, 192, 194, 196, 198, 199. For instance, if an arc fault 42 is determined to be occurring between the output 172 of the first secondary distribution unit 184 and the input 178 of the first electrical load 20, remedial measures can be controlled, executed, or the like, to only interrupt the portion of the power distribution system 130 affected by the arc fault 42 (e.g. just the span between the output 172 and the input 178). Thus, non-limiting aspects of the disclosure can be included wherein, for example, the supply of power to the second electrical load 120 is not interrupted by the arc fault 42 detection and remediation.

While the power distribution system 130 shown has only Primary and Secondary distribution units 180, 182, aspects of the disclosure can be applied to more complex systems with further levels (tertiary distribution units, etc.) and to power buses, power feeders, or the like, associated with the power sources 32, electrical loads 20, 120, or the like.

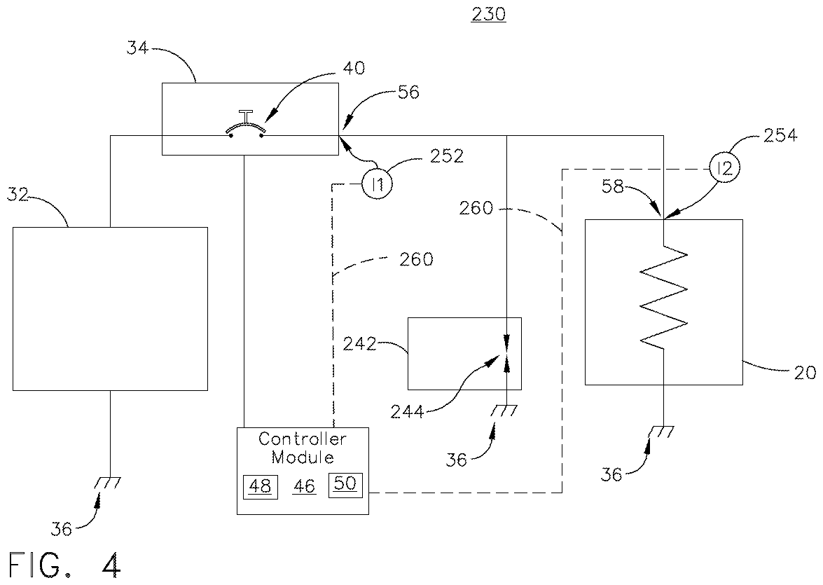

FIG. 4 illustrates another power distribution system 230 according to another aspect of the present disclosure. The power distribution system 230 is similar to the power distribution systems 30, 130; therefore, like parts will be identified with like numerals increased by 200, with it being understood that the description of the like parts of the power distribution systems 30, 130 applies to the power distribution system 230, unless otherwise noted. One difference is that the power distribution system 230 includes power characteristic sensors in the form of current sensors 252, 254 communicatively connected with the controller module 46. In this non-limiting aspect of the disclosure, the positioning of first and second current sensors 252, 254 at the respective SSPC output 56 and electrical load input 58 can be utilized to determine when or if an arc fault 242 is or has occurred, such as a parallel arc fault 244, wherein an energized conductor arcs to an electrical ground 36; that is, the arc fault 244 is parallel with the electrical load 20. While the parallel arc fault 244 is shown arcing to the electrical ground 36, non-limiting aspects of the disclosure can be included wherein the arcing is directed to any other conductive component, device, element, or the like, having a different potential than the power source 32.

The power distribution system 230 can determine if a current difference indicates an arc fault 242 is or has occurred. As used herein, a current difference is a difference between a current supplied at the upstream component such as the output 56 of the SSPC 34, as measured by the first current sensor 252, and a current received at the downstream component, such as the input 58 of the electrical load 20, as measured by the second current sensor 254.

Non-limiting aspects of the disclosure can be included wherein the controller module 46 is configured or adapted to improve the detection sensitivity (and reduce the probability of false detections) by determining a current difference between a set of respective current sensors 252, 254, comparing the determined current difference with a value, threshold, range, or the like to minimize the effect of the errors in sensing, measuring, or determining the respective current values, enabling the current difference method to be effective without the expense and complexity of implementing high accuracy current measurements in every power distribution system location, component, node, or the like.

This scenario is typical for a vehicle application such as an aircraft with a metallic chassis. Since the arc fault is in parallel with the load it will usually increase the total current flow through the circuit breaker and hence it might trip the circuit breaker. However, there is a significant probability that the impedance of the arc fault loop will be sufficient to limit the current to a value that the circuit breaker will maintain for a considerable period of time.

Initially, during a parallel arc fault 244, the fault current, particularly if it is due to tracking or intermittent arcing, may only cause a modest extra power draw, so that the electrical load 20 can continue to operate normally, and the power distribution system 230 continues to operate without indication of a fault, unaware of the problem. However, the arcing is likely to increase the local damage which will typically increase the leakage or arc fault current over time, with consequences of increasing the heat produced at the fault location. Alternatively, in another non-limiting aspect of the disclosure, a parallel arc fault 244 can increase the total current flowing through the upstream device (e.g. the SSPC 34).

To detect this arc fault 242, the controller module 46 receives or determines a respective current sensed at each current sensor 252, 254, and determines a current difference between the two sensed values. A difference in the readings of the two meters, would indicate the presence of a parallel arc fault 244. However, the desire to reduce or prevent nuisance trips, described herein, remains.

During normal power distribution system 230 operations (e.g. non-fault conditions), the expectation that the current supplied from the SSPC 34 output 56 would be equal to, or match the current received at the electrical load 20 input 58 (for instance, within a margin of error). In one non-limiting example, the error margins of each sensed or measured current can exceed plus or minus 2.5%, and hence a parallel arc fault 244 that progressively increases in intensity may not be detected in the earlier stages that are more benign from a safety viewpoint due to comparatively small current drop determined by the controller module 46, especially when adapted or configured to avoid nuisance trips. Thus non-limiting aspects of the disclosure can incorporate a non-limiting set of considerations adapted or configured to minimize the effect of the errors in each current difference determination by the controller module 46.

In one non-limiting example of FIG. 4, the power distribution system 230 can include a 200 Amp maximum conductor with an error measurement of uncertainty of plus or minus 2.5%. In the above-mentioned examples, a maximum threshold value or range can be determined. For instance, if the actual current supplied at the SSPC 34 output 56 is 20 Amps, the maximum 2.5% error sensed can be 25 Amps (20 Amps plus 2.5% of 200 Amps). In similarly non-faulted state (e.g. wherein the full 20 Amps is delivered to the electrical load 20 input 58), the smallest current sensed can be 15 Amps (20 Amps minus 2.5% of 200 Amps). Thus the largest current difference can be the differences between the first and second sensed currents can be 10 Amps for a non-fault determination. In a power distribution system 230 with bi-directional current, using the above-example, could result in current difference of—10 Amps for a non-fault determination. Thus, any determination of current difference between −10 Amps and 10 Amps could be considered fault-free.

Furthermore, aspects of the disclosure can be included wherein each current measurement point is always measured by the same power characteristic sensor, current sensor 252, 254, or the like, and similarly, the circuit and interconnecting conductor remains the same (e.g. unless replaced during maintenance, etc.). Thus, the error discrepancies should also remain unchanged providing the sensed or measured power characteristic conditions, such as temperature and current flow, are appropriately considered. Thus, in non-limiting aspects of the disclosure, the detection of an arc fault 242 can be achieved by discovering an unexpected change of observed current measurements even though it is smaller than the absolute error margins. However, the observed current difference can be affected by a number of factors including the current flow at that moment in time. A non-limiting set of factors and approaches to minimize their influence on the sensitivity of the fault detection capability, are included above, and are equally applicable to the power distribution system 230. The factors or considerations can include environmental conditions of the power distribution system 230 such as current and temperature, timing factors, or the like, as described herein. While aspects of the disclosure can include all of factors described herein, it is appreciated that an implementation using a subset of the factors can provide a sufficient sensitivity improvement.

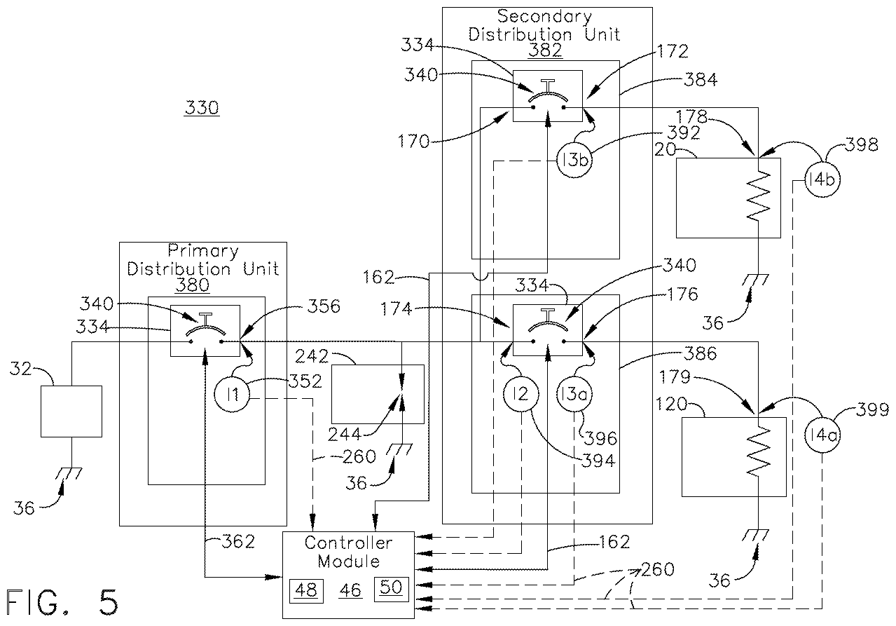

FIG. 5 illustrates another power distribution system 330 according to another aspect of the present disclosure. The power distribution system 330 is similar to the power distribution systems 30, 130, 230; therefore, like parts will be identified with like numerals increased by 300, with it being understood that the description of the like parts of the power distribution systems 30, 130, 230 applies to the power distribution system 330, unless otherwise noted. One difference is that the power distribution system 330 includes multi-tiered power distribution network, described below.

As shown, the power distribution system 330 can include the power source 32 connected upstream of a primary power distribution unit 380, which is further connected upstream in parallel with a set of secondary power distribution units 382, shown as a first secondary power distribution unit 384 and a second secondary power distribution unit 386. The primary distribution unit 380 can include an SSPC 334 having a switching element 340, and a power characteristic sensor, such as a first current sensor 352, positioned at an output 356 of the SSPC 334 or the primary distribution unit 380. The SSPC 334 or the switchable element 340 can be controllably or communicatively connected with the controller module 46 by way of a signal output pathway 362.

The first secondary distribution unit 384 can include an SSPC 334 having a switching element 340, and at least one a power characteristic sensor, such as a third current sensor 392 positioned at an output 172 of the SSPC 334 or the first secondary distribution unit 384. The second secondary distribution unit 386 can include an SSPC 334 having a switching element 340, and at least one a power characteristic sensor, such as a fourth current sensor 394 positioned at an input 174 of the SSPC 334 or the second secondary distribution unit 386 and a fifth current sensor 396 positioned at an output 176 of the SSPC 334 or the second secondary distribution unit 386. In non-limiting examples, each of the SSPCs 334 or switching elements 340 can be controllably or communicatively connected with the controller module 46 by way of a respective signal output pathway 162.

As shown, the output 172 of the first secondary distribution unit 384 can be connected upstream of a first electrical load 20 at an input 178. A power characteristic sensor, such as a sixth current sensor 398 can be positioned at the input 178 of the first electrical load 20. Also as shown, the output 176 of the second secondary distribution unit 386 can be connected upstream of a second electrical load 120 at an input 179. A power characteristic sensor, such as a seventh current sensor 399 can be positioned at the input 179 of the second electrical load 120. Each respective current sensor 352, 392, 394, 396, 398, 399 can further be communicatively connected with the controller module 46, for instance, by way of communication lines 260, and can provide the sensed current, or a communication representative thereof, to the controller module 46.

As described herein, aspects of the disclosure enable, or otherwise are adapted or configured to the improve detection sensitivity by applying knowledge of the different manners in which the observed currents will be affected by an arc fault 242 and by measurement errors, thereby minimizing the allowance that must be made for the measurement errors and consequently improving the arc fault 242 detection sensitivity.

Non-limiting aspects of the disclosure can be configured or adapted to sense or measure the current at at least two locations in each power distribution system 330 to determine the current difference between the at least two locations. For instance, non-limiting aspects of the disclosure can detect, calculate, or otherwise determine a current difference between at least two locations of the power distribution system 330, such as between the output 356 of the primary power distribution unit 380 and the summation of currents received at the inputs 170, 174 of the secondary distribution units 382, between the output 172 of the first secondary distribution unit 384 and the input 178 of the first electrical load 20, between the output 176 of the second secondary distribution unit 386 and the input 179 of the second electrical load 120, or a combination thereof. As shown, the first secondary distribution unit 384 does not include a current sensor positioned at the input 170, but the current received can be calculated, determined, or the like, or compared with expected results, as needed. In this sense, only a subset of inputs or outputs 356, 170, 172, 174, 176, 178, 179 can be configured with current sensors.

As described herein, the respective current sensors 352, 392, 394, 396, 398, 399 can sense or measure the respective currents at the respective inputs or outputs 356, 172, 174, 176, 178, 179. In another non-limiting example, the sensed or measured currents from the respective current sensors 352, 392, 394, 396, 398, 399 can be supplied, provided, delivered, or communicated to the controller module 46, which can be adapted or configured to determine the current difference between respective locations 356, 170, 172, 174, 176, 178, 179. Detection of a current difference exceeding a value, threshold, range, or the like can imply an arc fault 242 condition, such as the parallel arc fault 244. Non-limiting aspects of the disclosure can be included wherein the power distribution system 330, the controller module 46, or the like, can define a set of values, thresholds, ranges, or the like, such that each electrical span between respective current sensors 352, 392, 394, 396, 398, 399 can define an individual threshold.

Furthermore, non-limiting aspects of the disclosure can be included wherein the controller module 46 can be configured or adapted to determined where the arc fault 242 is or has occurred, based on the respective sensed currents received from the set of current sensors 352, 392, 394, 396, 398, 399. For instance, if an arc fault 242 is determined to be occurring between the output 172 of the first secondary distribution unit 384 and the input 178 of the first electrical load 20, remedial measures can be controlled, executed, or the like, to only interrupt the portion of the power distribution system 330 affected by the arc fault 242 (e.g. just the span between the output 172 and the input 178). Thus, non-limiting aspects of the disclosure can be included wherein, for example, the supply of power to the second electrical load 120 is not interrupted by the arc fault 242 detection and remediation.

While the power distribution system 330 shown has only Primary and Secondary distribution units 380, 382, aspects of the disclosure can be applied to more complex systems with further levels (tertiary distribution units, etc.) and to power buses, power feeders, or the like, associated with the power sources 32, electrical loads 20, 120, or the like.

Many other possible aspects and configurations in addition to that shown in the above figures are contemplated by the present disclosure. For example, further non-limiting aspects of the disclosure can be included, wherein a combination of voltage and current sensors are adapted or configured to detect series and parallel arc faults in a power distribution system. Additionally, the design and placement of the various components can be rearranged such that a number of different in-line configurations could be realized.

The aspects disclosed herein provide an apparatus and method for detecting electrical faults in a power distribution system. The technical effect is that the above described aspects enable the detecting or confirming of electrical faults in a circuit, and providing indication or remediation of such faults. One advantage that can be realized in the above aspects is that the above described aspects provide for active detection of arcing electrical faults, and thus reducing erroneous false-positive fault indications, reducing nuisance tripping.

Another advantage of the above described aspects is that the detection of the arc can be precisely determined where the arc is occurring. This can allow for a very robust system wherein arcing events can be quickly located (and safely interrupted) due to the proximity of one or more arc power characteristic sensors to any given failure point. Additionally, by locating the point of failure, the system can allow for rerouting of power around the fault (if available), providing redundancy in the power distribution system. The above described aspects, thus, provide for increased safety for an aircraft electrical power distribution system and hence improve the overall safety of the aircraft and air travel. Furthermore, precisely defining where an electrical fault is taking place reduces or eliminates any additional maintenance time or costs associated with having to manually test and locate the electrical failure.

The disclosure describes a system and method for detection of a parallel arc fault or a series arc fault in the power distribution system with minimal increases in weight, volume and cost. In some power distribution systems like the power feeders inside an aircraft, hundreds of circuits controlled by solid state switches must be continually monitored. A system as described herein can include automating the detection of faults where manual detection is unreasonable.

Although existing contemporary power distribution units incorporate voltage and current monitoring, the accuracy of such intrinsic measurements is often too low to directly produce a sensitive, reliable arc detection function. By including factors or considerations in determining whether a fault is or has occurred, a more precise detection of faults can take place, potentially without modifying existing system components.

When designing aircraft components, important factors to address are size, weight, and reliability. The above described power distribution system results in a lower weight, smaller sized, increased performance, and increased reliability system. The lower number of parts and reduced maintenance will lead to a lower product costs and lower operating costs. Reduced weight and size correlate to competitive advantages during flight.

To the extent not already described, the different features and structures of the various aspects can be used in combination with each other as desired. That one feature cannot be illustrated in all of the aspects is not meant to be construed that it cannot be, but is done for brevity of description. Thus, the various features of the different aspects can be mixed and matched as desired to form new aspects, whether or not the new aspects are expressly described. Combinations or permutations of features described herein are covered by this disclosure.

This written description uses examples to disclose aspects of the disclosure, including the best mode, and also to enable any person skilled in the art to practice aspects of the disclosure, including making and using any devices or systems and performing any incorporated methods. The patentable scope of the disclosure is defined by the claims, and can include other examples that occur to those skilled in the art. Such other examples are intended to be within the scope of the claims if they have structural elements that do not differ from the literal language of the claims, or if they include equivalent structural elements with insubstantial differences from the literal languages of the claims.

What is claimed is:

1. A power distribution system comprising:
an upstream electrical component having an output and a first power characteristic sensor configured to sense a power characteristic at the output;
a downstream electrical component having an input and a second power characteristic sensor configured to sense a power characteristic at the input;
a conductor conductively connecting the output with the input; and
a controller module having an arc fault threshold stored in memory and communicatively connected with the first and second power characteristic sensors and configured to determine if an arc fault is present by receiving a first sensed power characteristic from the first power characteristic sensor and a second sensed power characteristic from the second power characteristic sensor, determining a difference between the first and second sensed power characteristics, determining a calibration factor and modifying the arc fault threshold based on the calibration factor, comparing the difference with the modified arc fault threshold, and upon satisfaction of the comparison, providing indication of an arc fault at the conductor;
wherein the calibration factor includes at least one of a temperature factor, a current factor, or a timing factor.

2. The power distribution system of claim 1 wherein the calibration factor includes the timing factor and at least one of the temperature factor, or the current factor.

3. The power distribution system of claim 2 wherein satisfaction of the comparison includes exceeding the modified arc fault threshold for a period of time, wherein the period of time is related to the timing factor.

4. The power distribution system of claim 1 wherein the temperature factor is related to the actual or estimated temperature of the conductor.

5. The power distribution system of claim 1 wherein the current factor is related to the actual or estimated current traversing the conductor.

6. The power distribution system of claim 5 wherein the temperature factor is related to an estimated temperature of the conductor based on the current traversing the conductor.

7. The power distribution system of claim 6 wherein the temperature factor is further related to an estimated temperature of the conductor based on the current traversing the conductor over a period of time.

8. The power distribution system of claim 1 wherein the calibration factor includes at least one of a temperature factor over a period of time, or a current factor over a period of time.

9. The power distribution system of claim 1 wherein at least one of the upstream or downstream electrical components is a solid state power controller including a respective integrated first or second power characteristic sensor.

10. The power distribution system of claim 9 wherein the first power characteristic sensor is a voltage sensor, the second power characteristic sensor is a voltage sensor, and the controller module is configured to provide indication of a series arc fault upon satisfaction of the comparison.

11. The power distribution system of claim 9 wherein the first power characteristic sensor is a current sensor, the second power characteristic sensor is a current sensor, and the controller module is configured to provide indication of a parallel arc fault upon satisfaction of the comparison.

12. The power distribution system of claim 1 wherein the power distribution system includes an array of power characteristic sensors at a set of upstream and downstream electrical components, and wherein the controller module is configured to determine if an arc fault is present between two of the array of power characteristic sensors, and upon satisfaction of the comparison provide indication where in the power distribution system the arc fault is present.

13. A method for detecting arc faults in a power distribution system, the method comprising:
receiving, in a controller module, a first sensed power characteristic from a first power characteristic sensor at an output of an upstream electrical component;
receiving, in the controller module, a second sensed power characteristic from a second power characteristic sensor at an input of a downstream electrical component, the input and output connected by a conductor;
determining, by the controller module, a difference between the first and second sensed power characteristics;
determining, by the controller module, a fault threshold calibration factor;
modifying an arc fault threshold stored in memory of the controller module based on the fault threshold calibration factor;
comparing the determined difference with the modified arc fault threshold; and
upon satisfaction of the comparison, providing indication of an arc fault at the conductor;
wherein the fault threshold calibration factor includes at least one of a temperature factor, a current factor, or a timing factor.

14. The method of claim 13, wherein modifying the arc fault threshold include modifying the arc fault threshold based on the timing factor and at least one of the temperature factor, or the current factor.

15. The method of claim 14 wherein satisfaction of the comparison includes exceeding the modified arc fault threshold for a period of time, wherein the period of time is related to the timing factor.

16. The method of claim 15, further comprising taking remedial action to extinguish the arc fault, by the controller module.

17. The method of claim 13, further comprising repeatedly receiving the first sensed power characteristic, repeatedly receiving the second sensed power characteristic, repeatedly determining the fault threshold calibration factor, repeatedly modifying the arc fault threshold, and repeatedly comparing the determined difference with the modified arc fault threshold.

18. The method of claim 13, further comprising receiving the first and second sensed power characteristics from an array of power characteristic sensors at a set of upstream and downstream electrical components, and upon satisfaction of the comparison provide indication where in the array of power characteristic sensors the arc fault is present.

19. The method of claim 13, wherein the temperature factor is related to the actual or estimated temperature of the conductor, or wherein the current factor is related to the actual or estimated current traversing the conductor.

20. The method of claim 19 wherein the temperature factor is related to an estimated temperature of the conductor based on the current traversing the conductor.
